(19) United States
(12) Patent Application Publication
(10) Pub. No.: US 2026/0235311 A1
(43) Pub. Date: Aug. 13, 2026

(54) SYSTEMS AND METHODS FOR RECONSTRUCTION, IMAGING AND CONTROL OF AIRFLOW IN AN ENVIRONMENT

(71) Applicant: Mitsubishi Electric Research Laboratories, Inc., Cambridge, MA (US)

(72) Inventors: Arjun Teh, Pittsburgh, PA (US); Wael Ali, Brookline, MA (US); Joshua Rapp, Somerville, MA (US); Hassan Mansour, Newton, MA (US)

(73) Assignee: Mitsubishi Electric Research Laboratories, Inc., Cambridge, MA (US)

(21) Appl. No.: 19/050,676

(22) Filed: Feb. 11, 2025

(51) Int. Cl. F24F 11/63; F24F 110/30; G06T 15/06; G06T 15/50

(52) U.S. Cl. CPC F24F 11/63; G06T 15/06; G06T 15/506; F24F 2110/30

(57) ABSTRACT

A system for airflow control, reconstruction, and imaging comprises a memory storing computer-executable instructions and a processor configured to execute the instructions to control a Heating, Ventilation, and Air Conditioning (HVAC) system. The system includes a patterned background, a camera to capture two-dimensional (2D) images of airflow distortions caused by density variations, and a physics-informed neural network (PINN) for reconstructing a three-dimensional (3D) refractive field. The processor is further configured to compare the reconstructed 3D refractive field and thermal parameters with desired environmental parameters to identify deviations. Based on the deviations, the processor adjusts operational parameters of the HVAC system in real-time to ensure thermal comfort and energy efficiency. The system operates in an iterative feedback loop that continuously monitors the indoor environment by updating captured images, reconstructing the airflow, and dynamically refining HVAC control.

### TECHNICAL FIELD

The present disclosure generally relates to a system and method for control, reconstruction and imaging of airflow and more particularly to optical sensing and machine learning techniques to image and analyze three-dimensional airflow patterns in indoor environments.

### BACKGROUND

Airflow analysis and control is an aspect of environmental control for several real-world applications. Airflow control is required to maintain the desired environmental conditions in a wide range of real-world applications. For example, in heating, ventilation, and air conditioning (HVAC) systems, proper airflow management ensures the uniform distribution of temperature and humidity. Understanding the airflow in indoor spaces is crucial for improving the comfort and efficiency of heating, ventilation, and air conditioning (HVAC) systems. However, three-dimensional (3D) airflow sensing is challenging since hardware sensors only measure localized spatial regions around the sensors, and computationally aided systems rely on expensive computational fluid dynamics (CFD) simulations to predict airflow regimes. Alternatively, existing imaging techniques require expensive, precise optics for schlieren imaging or laser-induced fluorescence, or the injection of particles for particle image velocimetry (PIV). The ability to visualize and analyze airflow patterns is not only applicable for optimizing performance in HVAC systems but also vital for real-world applications such as air purification, industrial climate control, and refrigeration systems and so on, where precise airflow control directly impacts safety, efficiency, and functionality.

Accordingly, there is a need for efficient and robust systems and methods for effective analysis and control of airflow in three dimensional (3D) spaces.

### SUMMARY

Various example embodiments are directed towards airflow analysis and control using 3D refractive field of a transparent medium. Some example embodiments provide approaches for reconstructing 3D refractive field of a transparent medium using a single image sensor. Towards this end some example embodiments utilize or are based on BOS tomography techniques for reconstructing 3D refractive field of a transparent medium. In this regard, some embodiments measure changes in the refractive index of transparent medium such as air caused by variations in parameters such as temperature, pressure or density. In this way, various example embodiments provide an accurate representation of variations in airflow and thermal gradients.

Background-Oriented Schlieren (BOS) is an optical technique used to visualize and measure changes in the refractive index of transparent media, such as air, caused by variations in temperature, pressure, or density. By analyzing distortions in a patterned background observed through the medium, BOS enables the study of airflow, thermal gradients, and fluid dynamics. However, it is a realization of some embodiment that accurately reconstructing 3D fields from BOS measurements typically requires multiple cameras positioned at different angles to achieve angular diversity. This diversity resolves the spatial ambiguities inherent in projecting 3D phenomena onto 2D images. Some embodiments also recognize that deploying multiple cameras introduces challenges, including precise calibration, extensive data processing, and physical constraints in setups where camera placement is limited or invasive. Additionally, the high cost of multiple high-resolution cameras and the infrastructure needed for synchronization and data fusion make traditional BOS systems expensive and impractical for large-scale or real-world scenarios.

Various embodiments are based on the recognition that angular diversity plays a fundamental role in conventional BOS systems for reconstruction of 3D refractive fields. BOS imaging captures 2D projections of light ray distortions caused by refractive index variations, such as those induced by temperature gradients. However, some embodiments realize that these 2D measurements alone cannot uniquely determine the corresponding 3D structure, as multiple 3D fields may produce identical 2D projections. By using multiple cameras placed at different angles, BOS systems gain unique, overlapping perspectives of the refractive field, constraining the solution space and resolving ambiguities. However, the deployment of multiple cameras may not be practical and feasible in several applications. For example, the use of multiple cameras is marred by constraints pertaining to calibration, data processing, and physical size. Some example embodiments are therefore based on another realization that there is a need for alternative approaches for reconstructing 3D refractive fields without the use of multiple cameras

Physics-Informed Neural Networks (PINNs) offer a transformative approach to BOS by eliminating the need for angular diversity through the use of embedded physical constraints. PINNs integrate the governing equations of fluid dynamics, such as the Navier-Stokes and heat transfer equations, directly into the reconstruction process. These equations, which govern the conservation of mass, momentum, and energy in airflow systems, act as universal constraints that are valid across the entire domain. By enforcing these laws, PINNs provide “hidden perspectives” on the refractive field, filling in gaps left by the single-camera setup. For example, if temperature gradients are observed in one part of the flow, the physical laws allow the system to infer corresponding airflow patterns in adjacent regions, significantly reducing the need for multiple viewpoints.

Some embodiments realize that unlike available BOS systems that rely on hardware for angular diversity, PINNs resolve ambiguities computationally. Through regularization, PINNs penalize solutions that violate physical laws, narrowing the solution space to physically consistent options. This approach ensures that even sparse or incomplete data from a single viewpoint may be used to infer the 3D refractive field accurately. By embedding the physics directly into their network structure, PINNs effectively interpolate and extrapolate unobserved dimensions, replacing the need for physical angular diversity with computational diversity. As a result, PINNs transform BOS from a hardware-intensive method to a computationally driven process, making the system efficient, practical, and cost-effective.

It is also a realization of some embodiments that nonlinear ray tracing is a computational technique that models the bending of light rays as they traverse a medium with varying refractive indices, such as air influenced by temperature, pressure, or density gradients. This capability is pivotal in integrating Physics-Informed Neural Networks (PINNs) into Background-Oriented Schlieren (BOS) systems using a single camera. In BOS, distortions in a patterned background observed through the refractive medium are accurately mapped back to the 3D refractive field responsible for them. Without nonlinear ray tracing, this mapping may incorrectly assume straight-line light paths, leading to errors because refractive index variations cause light to deviate. These errors may propagate through the PINN, as it relies on accurately simulating how light interacts with the medium to compare observed distortions with physically valid predictions. By simulating the bending trajectories, nonlinear ray tracing ensures that the input data aligns with the physics modeled by the PINN, allowing the network to enforce physical constraints like conservation laws and infer the 3D refractive field with accuracy.

By leveraging governing equations as virtual observations and accurately modeling light propagation through heterogeneous density media. Some embodiments are directed towards a combination of PINNs along with nonlinear ray tracing to replace the angular diversity provided by multiple cameras with computational diversity, enabling precise 3D reconstructions while simplifying setups and reducing costs, making single-camera BOS systems practical and efficient. Such a combination simplifies BOS systems, broadens their applicability to practical, large-scale environments, and eliminates the prohibitive costs and constraints of traditional setups.

Accordingly, one embodiment discloses a background-oriented Schlieren (BOS) method suitable for reconstructing a three-dimensional (3D) refractive field of a transparent medium using a single camera. The method comprises capturing a two-dimensional (2D) image of a patterned background through the transparent medium using the camera. The method further comprises training a physics-informed neural network (PINN) to produce a change of the refractive index of the medium that reduces a difference between the captured 2D image and a 2D image reconstructed from the 3D refractive field using a nonlinear ray tracing, wherein the PINN incorporates governing equations of fluid dynamics into a loss function of the training to regularize solution space of the 3D refractive field by penalizing inconsistencies with the governing equations, The method further comprises generating a reconstructed 3D refractive field that corresponds to the change in the refractive index of the medium.

In yet another example embodiment, a method for controlling a heating, ventilation, and air conditioning (HVAC) system based on reconstructed three-dimensional (3D) airflow and thermal fields. The method comprises capturing a two-dimensional (2D) image of a patterned background through an indoor environment using a single camera, wherein the captured image is distorted due to variations in the refractive index of air caused by temperature and density gradients. The method further comprises reconstructing a 3D refractive field of the indoor environment by inputting the captured 2D image into a physics-informed neural network (PINN), wherein the PINN incorporates governing equations of fluid dynamics and heat transfer into its loss function to regularize the solution space and infer airflow, temperature, and pressure distributions. The method further comprises reconstructing a 3D refractive field of the indoor environment by inputting the captured 2D image into a physics-informed neural network (PINN), wherein the PINN incorporates governing equations of fluid dynamics and heat transfer into its loss function to regularize the solution space and infer airflow, temperature, and pressure distributions. The method further comprises comparing the reconstructed 3D airflow and thermal fields with desired environmental parameters to identify deviations, including uneven temperature zones, air leakage, or inefficient airflow patterns. The method further comprises adjusting operational parameters of the HVAC system in real-time based on the deviations identified. The adjustments include at least one of modifying airflow rates by controlling fan speeds, redirecting airflow by adjusting vent orientations, or changing temperature setpoints of heating or cooling units. The method further comprises continuously monitoring the indoor environment by updating the captured 2D image and adjusting operational parameters of the HVAC system to maintain thermal comfort and optimize energy efficiency.

### BRIEF DESCRIPTION OF THE DRAWINGS

The presently disclosed embodiments will be further explained with reference to the attached drawings. The drawings shown are not necessarily to scale, with emphasis instead generally being placed upon illustrating the principles of the presently disclosed embodiments.

FIG. 1A illustrates a block diagram of a system for airflow control, reconstruction and imaging, according to some embodiments;

FIG. 1B illustrates a workflow for systems and method for control, reconstruction and imaging of airflow, according to some embodiments;

FIG. 2A illustrates an exemplar embodiment illustrating the airflow within a three-dimensional volume is generated by a room air conditioner (RAC), according to some embodiments;

FIG. 2B is a diagram illustrating a comparison effect of an airflow that has a refractive field distribution on light rays propagating from a background texture to a camera, according to some embodiments;

FIG. 3A illustrates an embodiment setup with single projector and an camera for airflow control, reconstruction and imaging, according to some embodiments;

FIG. 3B illustrates an embodiment setup with multiple projector and an camera for airflow control, reconstruction and imaging, according to some embodiments;

FIG. 4 illustrates the generation of BOS measurement from the schlieren effect for airflow control, reconstruction and imaging, according to some embodiments;

FIG. 5 illustrates a flow chart illustrating the physics informed nonlinear ray tracing reconstruction, according to some embodiments;

FIG. 6A illustrates a flow chart for updating airflow parameters by updating weights of multilayer perceptron (MLP), according to some embodiments;

FIG. 6B depicts a framework illustrating a multilayer perceptron (MLP) for evaluating a combination of distances of a BOS, according to some embodiments;

FIG. 7 depicts a flowchart illustrating the airflow control, reconstruction and imaging, according to some embodiments;

FIG. 8 depicts a flow chart of control feedback for HVAC system for airflow control, reconstruction and imaging, according to some embodiments;

FIG. 9 depicts a flow diagram illustrating a use case for airflow control, reconstruction and imaging, according to some embodiments; and

FIG. 10 illustrates some components of a system for airflow control, reconstruction and Imaging in an indoor environment, according to some embodiments;

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in art which fall within the scope and spirit of the principles of the presently disclosed embodiments.

### DETAILED DESCRIPTION

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like-reference numbers and designations in the various drawings may indicate like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine-readable medium. A processor(s) may perform the necessary tasks.

### Overview

Airflow refers to the movement of air in an indoor environment. In enclosed environments like buildings and rooms, effective airflow control is crucial for maintaining indoor air quality, thermal comfort, and energy efficiency. Industries such as HVAC (Heating, Ventilation, and Air Conditioning), healthcare, and industrial manufacturing rely on precise airflow regulation to ensure optimal environmental conditions. Proper airflow management helps in removing contaminants, balancing humidity, and optimizing ventilation, directly impacting occupant comfort and system efficiency.

Airflow analysis plays a role in various sectors, including residential, commercial, and industrial settings. Examples of such sectors include medical applications, chemical manufacturing process, pharmaceutical industry, food industry, where controlling airflow is vital for improving air quality, regulating temperature, and enhancing energy efficiency. For example, in pharmaceuticals, the transportation of sensitive drugs and vaccines requires precise temperature and airflow control to maintain their efficacy and prevent degradation. Even a small deviation in temperature or airflow can compromise the quality of the products, potentially leading to severe consequences for both public health and business operations.

To analyze airflow, conventional methods rely on fixed sensors that measure air velocity, temperature, and pressure at specific locations. However, placing sensors everywhere in a room is impractical due to both physical and financial constraints. For example, in a crowded indoor environment such as an office or classroom, every person moves within the space, altering airflow patterns. It is neither feasible nor cost-effective to attach sensors near each occupant or place a dense network of static sensors to track airflow in real time. Additionally, airflow behavior in enclosed indoor spaces is highly dynamic, influenced by factors such as open doors, windows, air conditioning vents, human movement, and furniture arrangement. Fixed sensors fail to capture the full spatial variation of airflow, leading to incomplete data and potential inaccuracies in HVAC optimization. The inability to relocate sensors dynamically further limits their effectiveness, as airflow patterns change throughout the day based on occupancy, external weather conditions, and changes in the layout of the space.

Despite the critical importance of airflow management, accurately visualizing and analyzing airflow remains a significant challenge. Some embodiments recognize that the visualization and reconstruction of airflow patterns in three-dimensional (3D) spaces are inherently complex tasks, hindered by several limitations. One key challenge is that conventional sensors provide localized airflow data, making it difficult to achieve a comprehensive understanding of airflow dynamics. Additionally, it is realized that available imaging techniques, such as schlieren imaging and particle image velocimetry (PIV), require sophisticated and costly setups which rely on the use of multiple cameras or imaging devices placed at different angles to reconstruct 3D airflow patterns. This approach is both prohibitively expensive and invasive, requiring extensive setups that include numerous cameras and patterned backgrounds. Such configurations are impractical for real-world applications like room-scale airflow analysis, where space and budget constraints are common.

In order to achieve the aforementioned objectives and challenges, various embodiments provide systems, methods, and for control, reconstruction and imaging of airflow. To overcome these challenges some embodiments provide measures to control the various parameters of air vents which includes controlling the opening/closing of ducts, speed of fan, and/or temperature of an HVAC system conditioning the air of the environment. In this regard, various example embodiments identify locations or regions within a closed environment. Towards this end, various embodiments utilize an imaging device such as a camera and process the captured images using an integrated approach that utilizes Background-Oriented Schlieren (BOS) imaging and Physics-Informed Neural Networks (PINNs).

BOS is an optical technique used to visualize and measure changes in the refractive index of transparent media, such as air, caused by variations in temperature, pressure, or density. By analyzing distortions in a patterned background observed through the medium, BOS enables the study of airflow, thermal gradients, and fluid dynamics. BOS imaging makes a viable option for environments where airflow changes rapidly due to factors like human movement, HVAC operation, or changes in room layout.

However, accurately reconstructing 3D fields from BOS measurements typically requires multiple cameras positioned at different angles to achieve angular diversity. This diversity resolves the spatial ambiguities inherent in projecting 3D phenomena onto 2D images. Unfortunately, deploying multiple cameras introduces challenges, including precise calibration, extensive data processing, and physical constraints in setups where camera placement is limited or invasive. Additionally, the high cost of multiple high-resolution cameras and the infrastructure needed for synchronization and data fusion make traditional BOS systems expensive and impractical for large-scale or real-world scenarios.

The embodiments presented are based on the recognition that angular diversity plays a fundamental role in traditional BOS systems, enabling the accurate reconstruction of 3D refractive fields. BOS imaging captures 2D projections of light ray distortions caused by refractive index variations, such as those induced by temperature gradients. However, these 2D measurements alone cannot uniquely determine the corresponding 3D structure, as multiple 3D fields can produce identical 2D projections. To address this challenge, various embodiments utilize physics-informed neural networks (PINNs) with the BOS imaging technique to generate a reconstructed 3D refractive field for the monitored environment.

PINNs offer a transformative approach to BOS by eliminating the need for angular diversity through the use of embedded physical constraints. PINNs integrate the governing equations of fluid dynamics, such as the Navier-Stokes and heat transfer equations, directly into the reconstruction process. These equations, which govern the conservation of mass, momentum, and energy in airflow systems, act as universal constraints that are valid across the entire domain. By enforcing these laws, PINNs provide “hidden perspectives” on the refractive field, filling in gaps left by the single-camera setup.

Unlike traditional BOS systems that rely on hardware for angular diversity, PINNs resolve ambiguities computationally. Through regularization, PINNs penalize solutions that violate physical laws, narrowing the solution space to physically consistent options. This approach ensures that even sparse or incomplete data from a single viewpoint can be used to infer the 3D refractive field accurately. By embedding the physics directly into their network structure, PINNs effectively interpolate and extrapolate unobserved dimensions, replacing the need for physical angular diversity with computational diversity. As a result, PINNs transform BOS from a hardware-intensive method to a computationally driven process, making the system more efficient, practical, and cost-effective.

In addition, nonlinear ray tracing is a computational technique that models the bending of light rays as they traverse a medium with varying refractive indices, such as air influenced by temperature, pressure, or density gradients. This capability is pivotal in integrating Physics-Informed Neural Networks (PINNs) into Background-Oriented Schlieren (BOS) systems using a single camera. In BOS, distortions in a patterned background observed through the refractive medium must be accurately mapped back to the 3D refractive field responsible for them. Without nonlinear ray tracing, this mapping would incorrectly assume straight-line light paths, leading to errors because refractive index variations cause light to deviate. These errors would propagate through the PINN, as it relies on accurately simulating how light interacts with the medium to compare observed distortions with physically valid predictions. By simulating the bending trajectories, nonlinear ray tracing ensures that the input data aligns with the physics modeled by the PINN, allowing the network to enforce physical constraints like conservation laws and infer the 3D refractive field with high accuracy.

By leveraging governing equations as virtual observations and accurately modeling light propagation through heterogeneous density media, the combination of PINNs along with nonlinear ray tracing replaces the angular diversity provided by multiple cameras with computational diversity, enabling precise 3D reconstructions while simplifying setups and reducing costs, making single-camera BOS systems practical and efficient. This innovation simplifies BOS systems, broadens their applicability to practical, large-scale environments, and eliminates the prohibitive costs and constraints of traditional setups.

For instance, the system can identify areas of uneven temperature or inefficient airflow and dynamically adjust HVAC settings to address these issues. The BOS system can also monitor airflow anomalies, such as blockages or leaks, and trigger maintenance alerts, ensuring the HVAC system operates efficiently. This integration of BOS imaging and PINNs enables real-time, precise monitoring of airflow patterns. The BOS continuously updates airflow and temperature data, allowing real-time adjustments to HVAC operations. The proposed method may be combined with predictive algorithms to anticipate HVAC needs based on historical patterns and occupancy trends. These steps ensure the BOS and PINN system is seamlessly integrated into the HVAC infrastructure, providing a practical and efficient solution for improving thermal comfort and energy management in buildings.

Various embodiments have several practical applications across diverse industries and research fields such as HVAC Optimization in Buildings, Data Center Cooling, Automotive and Aerospace Engineering, Thermal Management in Electronics, Wind Energy Optimization and Process Optimization in Industrial Systems. These practical applications are driven by the ability to replace expensive, hardware-intensive multi-sensor systems with a faster and reliable computational framework, making it efficient, cost-effective, and broadly applicable.

### Overview of the System and Method for Airflow Analysis

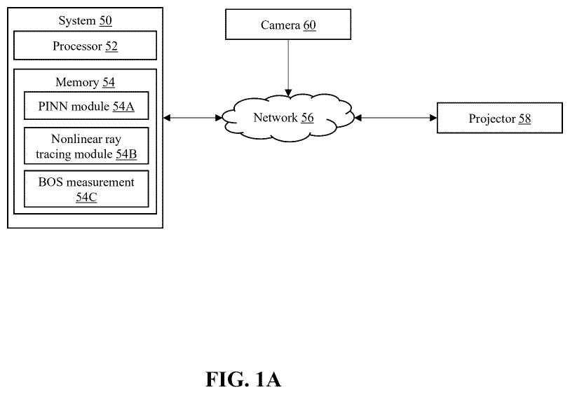

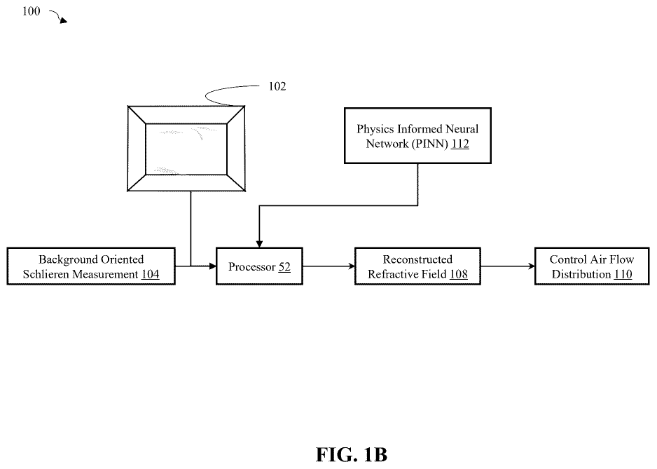

FIG. 1A illustrates a block diagram of a system 50 for airflow control, reconstruction and imaging, according to some embodiments. The system 50 is coupled through network 56 to one or more other components such as camera 60 and a projector 58. The memory module 54 stores the data hosting specialized modules that drive the intelligence of the system 50.

The memory 54 may store instructions that are executable by the system 50 and any data that may be utilized by the methods and systems of the present disclosure. The memory 54 may include random access memory (RAM), read only memory (ROM), flash memory, or any other suitable memory systems. The memory 54 may be a volatile memory unit or units, and/or a non-volatile memory unit or units. The memory 54 may also be another form of computer-readable medium, such as a magnetic or optical disk.

The memory 54 further includes a PINN module 54A, a nonlinear tracing module 54B and a BOS measurement 54C. The PINN module 54A is responsible for reconstructing the 3D refractive field by minimizing inconsistencies between observed BOS images and simulated data while adhering to governing equations, such as the Navier-Stokes and heat transfer equations. Beyond this, the PINN module 54A incorporates boundary conditions to refine physical consistency, adapts to various domains (e.g., turbulent flows) through domain-specific training, and supports optimization tasks, such as improving airflow distribution in HVAC systems or identifying thermal hotspots in data centers. The nonlinear ray tracing module 54B calculates light ray trajectories through the refractive field, using quasi-linear approximations to balance computational cost and accuracy. In addition, this nonlinear ray tracing module 54B handles complex refractive fields with steep gradients, validates ray-traced outputs against experimental setups and incorporates real-time computational optimizations for continuous monitoring. The BOS measurement module 54C processes the captured BOS images, calculates differences between observed and reconstructed 2D images, and derives changes in the refractive index. Furthermore, the BOS measurement module 54C preprocesses captured images to improve signal quality, applies advanced image filtering techniques to reduce noise, and generates quantitative outputs for further analysis.

The processor 52 of the system 50 executes instructions and performs computations. For example, the processor 52 processes data received from camera 60, and projector 58, which are integral to capturing and projecting the patterned background used in the BOS imaging system. The processor 52 analyzes the BOS images to derive meaningful information about the refractive field, temperature, airflow, and pressure distributions in the medium. The processor 52 runs advanced machine learning models, including Physics-Informed Neural Networks (PINNs), to reconstruct 3D refractive fields by optimizing the consistency of the BOS measurements with physical governing equations such as Navier-Stokes and heat transfer equations. Additionally, the processor 52 may manage complex ray-tracing computations also to model light propagation through the refractive index field accurately. By coordinating with the BOS measurement and nonlinear ray-tracing modules, the processor 52 executes real-time adjustments to the HVAC system, such as dynamically optimizing fan speeds, adjusting vent positions, and modifying thermostat setpoints based on the real-time airflow and temperature data. The processor 52 drives optimization processes, such as improving airflow distribution in HVAC systems, identifying thermal gradients, and mitigating hotspots in data centers. This facilitates decision-making by evaluating the reconstructed 3D field against desired environmental parameters such as target temperature, airflow rates, and pressure levels. Based on the evaluation, the processor 52 dynamically adjusts HVAC components, including fan speed, vent positions, and thermostat settings, and further integrates system 50 feedback to refine projections and analyses, ensuring continuous and adaptive monitoring of the environment.

The camera 60 captures two-dimensional (2D) images of a patterned background through the transparent medium. The captured images are distorted by variations in the refractive index caused by changes in airflow, temperature, or pressure fields within the medium. The camera 60 may provide high-resolution images, ensuring the clarity and precision required for generating BOS measurements. These images serve as input for the PINN module 54A stored within the memory 54 and executed by the processor 52, enabling the reconstruction of three-dimensional (3D) refractive fields. The camera 60 operates in synchronization with the projector 58, capturing the patterned background under various environmental conditions for detection and analysis of refractive index changes.

The projector 58 illuminates a textured or patterned background onto a wall or target surface within the indoor environment being analyzed. The projector 58 ensures uniform illumination and generates a well-defined pattern that serves as a reference for the BOS measurements. By projecting the pattern through the transparent medium, the system 50 introduces angular information of the 3D reconstruction process. In some embodiments, the projector 58 may be spatially offset from the camera 60, creating the necessary geometry for capturing angular distortions caused by refractive index variations.

The network 56 communicatively couples various components of the airflow analysis system such as the camera 60, the processor 52, the projector 58, and the memory 54, to communicate effectively over a wireless or wired medium. The network 56 may be implemented using a variety of technologies to suit different operational contexts. Wired networks, such as Ethernet or fiber optic connections may be ideal for stationary or highly secure installations, offering high-speed and reliable communication. Conversely, wireless networks, including Wi-Fi, 5G, Zigbee, LoRa WAN, and satellite communication, provide flexibility and scalability for mobile or remote operations. The network 56 may include hardware components such as modems, Wi-Fi transceivers, or other communication devices responsible for establishing a connection to the wider network, enabling data transmission. Software within the network 56 may be responsible for packetizing and de-packetizing data for network communication or managing communications over a cloud-based platform. In some embodiments, the network 52 combines control and forwarding functions on the same physical hardware, while in other cases, these functions might be split, with the control functions managed by external network devices in configurations such as software-defined networking (SDN). The network 52 ensures that data generated by the camera 60 or other data collection units/sensors is transmitted to the processor 56 or external systems for analysis.

FIG. 1B illustrates a workflow 100 for systems and method for control, reconstruction and imaging of airflow, according to some embodiments. The workflow 100 utilizes an integrated Background-Oriented Schlieren (BOS) and Physics-Informed Neural network (PINN)-approach for monitoring and optimizing airflow distribution within an indoor environment. The workflow 100 includes observing the refractive field 102 in a three-dimensional environment, the refractive field 102 representing variations in air density and temperature caused by airflow. The variations influence how light travels through the medium. The information regarding variations in air density and temperature is required for understanding airflow patterns, temperature distribution, and pressure dynamics within a space. To capture the refractive field 102, the BOS measurement 104 is performed. Towards this end, a projector projects or illuminates a background pattern typically a grid or a series of stripes on a wall or a target surface within the monitored indoor environment. The air within the indoor environment distorts the light passing through it, causing the background pattern to shift. A camera positioned to observe the illuminated background captures 2D images of airflow distortions caused by temperature and density variations. The resulting 2D images show how the pattern is altered by the refractive properties of the air. The key to this method lies in the fact that small variations in refractive index cause measurable distortions in the pattern, providing indirect but highly informative data about the environment's thermal and airflow characteristics.

The captured BOS images are processed by a processor 52 that performs the computational task of reconstructing the 3D refractive field. It may be noted that the workflow 100 only requires image from a single camera. Instead of using multiple cameras to gain overlapping perspectives of the refractive field, the workflow 100 uses a Physics-Informed Neural Networks (PINN) 112 to provide a transformative approach to BOS by eliminating the need for angular diversity through the use of embedded physical constraints. Thus, unlike conventional BOS systems that rely on hardware for angular diversity, the PINN 112 resolves the ambiguities computationally. According to some embodiments, the PINN 112 integrates the governing equations of fluid dynamics, such as the Navier-Stokes and heat transfer equations, directly into the reconstruction process. These equations, which govern the conservation of mass, momentum, and energy in airflow systems, act as universal constraints that are valid across the entire domain. By enforcing these laws, the PINN 112 provides “hidden perspectives” on the refractive field, filling in gaps left by the single-camera setup. For example, if temperature gradients are observed in one part of the flow, the physical laws allow the system to infer corresponding airflow patterns in adjacent regions, significantly reducing the need for multiple viewpoints.

The processor 52 invokes the PINN 112 to process the 2D images captured as BOS measurements. The PINN 112 enables the processor 52 to process the distorted images by embedding the Navier-Stokes and heat transfer equations to infer the 3D distribution of temperature, airflow, and pressure. Nonlinear ray tracing simulates how light behaves as it passes through the refractive medium, accounting for the complex, nonlinear changes in the refractive index due to temperature and airflow variations. The workflow 100 integrates physical principles, such as fluid dynamics and heat transfer, into the reconstruction process to ensure that the resulting 3D field adheres to the governing laws of physics. The reconstructed 3D refractive field 108 provides a comprehensive view of the temperature, pressure, and airflow distributions across the entire monitored space. This reconstructed 3D refractive field 108 is used for detecting variations or anomalies related to airflow in the indoor environment.

For example, in a room with uneven heating or cooling, the reconstructed 3D refractive field 108 may indicate regions where the density of air may be different from that of most of the other regions in the room. Such a region may be inferred as a region where air may not be circulating properly or where there are temperature imbalances. The data of the reconstructed 3D refractive field 108 may also highlight areas where airflow may be blocked or where there is excessive heat buildup. Examples of such areas include nearby equipment or air conditioning vents. With at least one such affected region identified, the data of the reconstructed 3D refractive field 108 may be used to control the airflow distribution 110 in real-time. The reconstructed 3D refractive field 108 is then integrated into the HVAC control system via a feedback loop to control airflow distribution 110. This involves mapping the airflow and temperature information to control parameters, such as fan speeds, vent positions, and thermostat setpoints. For instance, areas of uneven temperature or inefficient airflow may be identified, and the HVAC settings may be dynamically adjusted to address these issues. According to some embodiments, the workflow 100 may also comprise operations for monitoring airflow anomalies, such as blockages or leaks, and triggering maintenance alerts, ensuring the HVAC system operates efficiently.

Additionally, or optionally, the workflow 100 may also comprise operations for continuous monitoring and optimization of airflow and air conditioning. The airflow and temperature data may be continuously updated allowing real-time adjustments to HVAC operations. in some embodiments, the workflow 100 and its set up may also be combined with predictive algorithms to anticipate HVAC needs based on historical patterns and occupancy trends. These steps ensure the BOS and PINN system is seamlessly integrated into the HVAC infrastructure, providing a practical and efficient solution for improving thermal comfort and energy management in buildings.

According to some embodiments, the processor 52 may correlate the reconstructed 3D refractive field 108 with desired environmental parameters, such as optimal temperature zones or specific airflow patterns, and control the HVAC system by modifying fan speed, adjusting vent positions or alter temperature set points in the indoor environment accordingly. For instance, the processor 52 may command an HVAC controller to modify fan speeds, adjust vent positions, or alter the temperature setpoints of HVAC units based on the identified deviations from the ideal conditions. In practice, this means that the system 50 may automatically respond to changing environmental conditions, such as the presence of more people in a room or fluctuating outdoor temperatures, by adjusting the internal HVAC settings to maintain comfort and efficiency.

This entire process may be continuous, with the system 50 constantly monitoring the environment and updating the airflow and thermal conditions as required. The BOS measurement 104 is captured periodically, and the processor 52 processes and continuously updates the reconstructed 3D refractive field 108, ensuring that the airflow and temperature conditions remain optimal over time. This dynamic feedback loop makes the system 50 effective for environments where real-time adjustments are needed, such as in data centers, where maintaining specific temperature ranges is essential to prevent overheating of sensitive equipment, or in cleanrooms, where precise airflow control is vital to maintain sterile conditions.

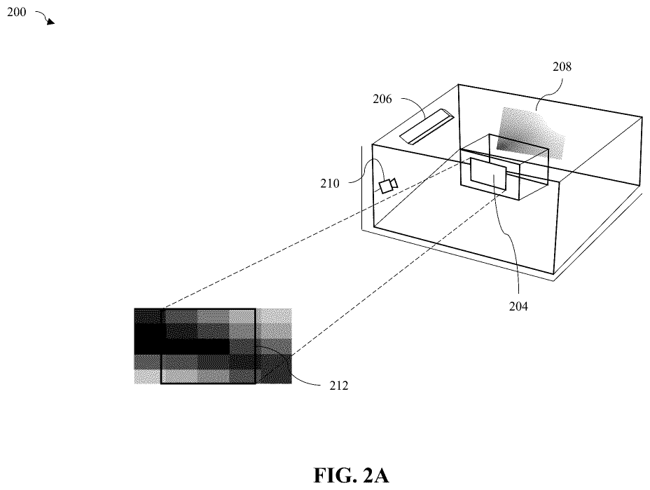

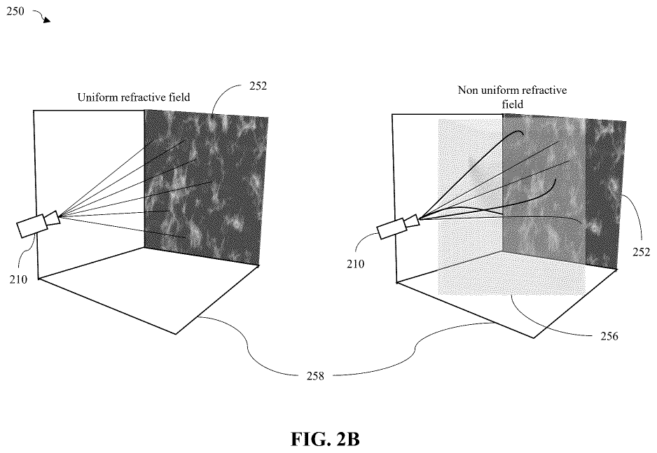

FIG. 2A illustrates an exemplary embodiment illustrating the airflow within a three-dimensional volume, according to some embodiments. FIG. 2A shows an environment 200, which includes a room air conditioner (RAC) 206, a camera 210 and a region of interest 204. The room air conditioner (RAC) 206 may be the primary source of airflow within the indoor environment or a room. The RAC 206 creates a controlled airflow in a space within the indoor environment, influencing the temperature and density of the air. This airflow may be monitored for assessing how the system 50 distributes air throughout the room, affecting both comfort and energy efficiency. The RAC's 206 may regulate the air temperature and ventilation within the environment, and its position and settings may directly impact the airflow dynamics observed by the camera 210.

The region of interest 204 refers to a specific portion of the room or volume of space which is selected for detailed monitoring. The region of interest 204 is particularly important because it contains the part of the airflow that the system 50 of FIG. 1A is configured to analyze for temperature and airflow patterns. The camera 210 is positioned in such a way that the camera 210 observes the region of interest 204, which lies within the influence of the airflow produced by the RAC 206. The camera 210 captures any distortions observed in the projected background pattern 208 caused by changes in temperature and air density within the region of interest 204. The captured data is processed to generate a refractive field map 212, which visually represents the distribution of temperature or airflow in the region of interest 204. The refractive field map 212 provides a clear and intuitive visualization of the environment's thermal gradients, highlighting areas of high and low temperature or inefficient airflow. This visualization helps to identify issues such as hotspots, areas of poor ventilation, or temperature imbalances within the space.

In one embodiment, the positioning of the camera 210 is placed on the wall parallel to the axis of the airflow and is directed towards the region of interest 204 as represented in FIG. 2A. The setup ensures that the camera 210 captures the airflow dynamics and thermal gradients caused by the RAC's 206 operation. On the opposite side of the camera 210, a textured background 208 is projected through the region of interest 204, providing a reference for observing how the air affects light passing through the region of interest 204. The BOS measurements are captured from the region of interest 204. The system 50 processes the data to reconstruct a 3D model of the airflow and temperature distributions. This model helps determine how well the RAC 206 is performing in distributing airflow throughout the room and whether any adjustments need to be made.

In another embodiment, the positioning of the camera 210 may be placed on one end of the RAC looking along the axis of air flow from the RAC 206. A projector may be placed for projecting a textured background pattern onto the wall that faces the RAC 206. In this configuration the camera continues to capture the airflow dynamics and thermal gradients caused by the RAC's 206 operation.

FIG. 2B is a diagram illustrating a comparison effect of an airflow that has a refractive field distribution on light rays propagating from a background texture to a camera, according to some embodiments. FIG. 2B shows an environment 250 illustrating the effect of airflow on light rays as the light rays propagate through a uniform refractive field and a non-uniform refractive field. FIG. 2B highlights how airflow 256 variations, in terms of temperature distribution, may affect the light rays used for BOS measurements, and how the effects may be analyzed to assess the quality and efficiency of airflow distribution within an environment. In this scenario, the camera 210 observes the indoor environment 258 where a patterned wall 252 is positioned to provide a reference for monitoring the airflow. The patterned wall 252 displays a background pattern that is distorted by the airflow in the indoor environment 258. In a scenario where there are no temperature variations in the airflow, the refractive field distribution is uniform (shown on the left view of FIG. 2B), Thus, the air density does not fluctuate significantly in a uniform or near-uniform refractive filed. In this case, the light rays from the patterned wall 252 travel in a straight line, as there are no variations in the refractive index of the medium (the air) to alter their paths. The uniform refractive field ensures that light rays move predictably and directly from the background on the patterned wall 252 to the camera 210 without any distortion.

However, when there are temperature variations within the airflow, the density distribution of the air changes. The temperature-induced changes cause the refractive field to become non-homogeneous or non-uniform. In such cases the refractive index of the air varies at different points within the air volume. As a result, the light rays that travel through the air are bent due to the differences in the refractive index (shown on the right view of FIG. 2B). This bending of light is the observable effect caused by the variations in temperature and air density within the non-uniform airflow 256 (having non-uniform refractive field). The light rays are no longer traveling in a straight line, as the light rays are refracted by the non-uniform density of the air. The bending of the rays is an indication of the changes in temperature and density in the airflow, which may be captured by the camera 210. By observing how the light rays deviate from their original path, the system 50 may infer the distribution of temperature and density within the airflow, providing information for understanding the behavior of the airflow and optimizing indoor climate control.

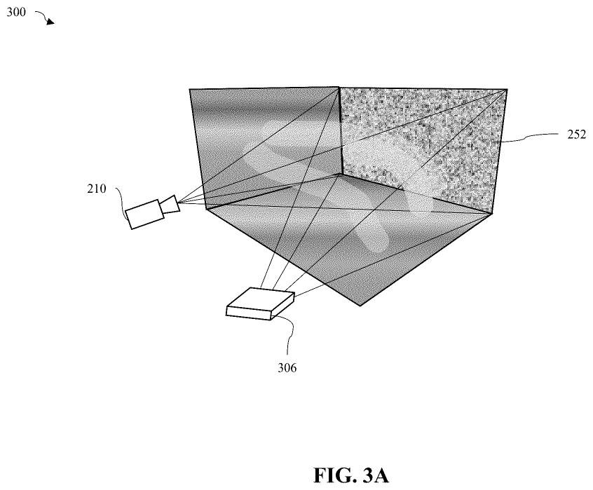

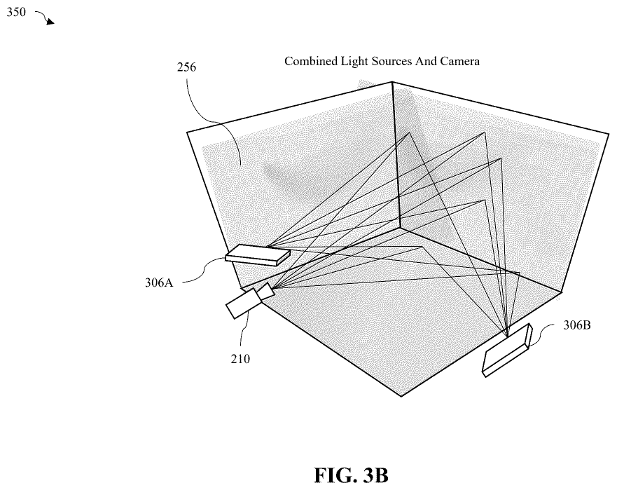

FIG. 3A illustrates an embodiment setup with a single projector and a camera with a patterned background for a wall for airflow control, reconstruction and imaging, according to some embodiments. FIG. 3A shows an environment 300 illustrating an embodiment of an imaging setup for a BOS system. The environment 300 shows a projector 306 and a camera 210, working in coordination to analyze the refractive changes in a three-dimensional volume. The projector 306 illuminates a backwall with a textured or patterned projection 252 for creating a visual reference for the system 50 of FIG. 1A. The camera 210 may be positioned at an offset angle from the projector 306 on a side opposite to the backwall on which the projection 252 is projected. This allows the camera 210 to observe the same backwall but capture a distorted version of the airflow of the patterned surface 252. The distortions are caused by density changes in the medium, such as variations in airflow, temperature, or pressure, which result in refractive index gradients. The camera 210 captures these distortions as input data for the BOS measurements. The BOS measurement module 54C stored in the memory 54 of FIG. 1A uses the captured data to reconstruct three-dimensional fields such as temperature, pressure, or velocity.

FIG. 3B illustrates an embodiment setup with multiple projectors 306A and 306B and a camera 210 for airflow control, reconstruction and imaging, according to some embodiments. FIG. 3B shows an environment 350 illustrating an embodiment of an advanced imaging setup designed to improve airflow analysis using a Background Oriented Schlieren system. In this setup, multiple projectors 306A and 306B may be positioned at different spatial offsets relative to a single camera 210. The projectors 306A and 306B illuminate a backwall with a textured or patterned projection which serves as a reference for observing distortions caused by density variations within the airflow 256. The use of multiple projectors 306A and 306B at varying offsets allows light rays to propagate through different sections of the airflow volume, enabling the camera 210 to capture diverse measurements of the flow field.

The configuration helps in multiple angles of illumination. The camera 210 records the distorted patterns projected on the back-wall, where each projector of the multiple projectors 306A and 306B contributes a unique perspective of the airflow. By integrating the multiple perspectives, the system 50 reconstructs a detailed and accurate three-dimensional representation of the density variations, such as airflow, temperature gradients, or pressure changes, within the observed volume. Light rays emitted from one projector (i.e., projector 306A) may illuminate regions of the volume closer to the camera 210, while rays from another projector (i.e., the projector 306B) may penetrate deeper into the airflow, capturing details of regions that are farther from the camera 210. This arrangement helps in a comprehensive sampling of the entire volume of interest, offering richer and more precise data for reconstruction.

In environmental monitoring, the setup may analyze large-scale airflow patterns in wind tunnels or controlled industrial environments, providing insights into turbulence and temperature fluctuations. In aerospace testing, the setup may capture airflow dynamics around aerodynamic surfaces like aircraft wings, helping in the design and optimization of efficient flight systems. Additionally, the setup is suitable for thermal flow analysis, such as studying heat dissipation in cooling systems, HVAC systems, or other scenarios involving temperature gradients.

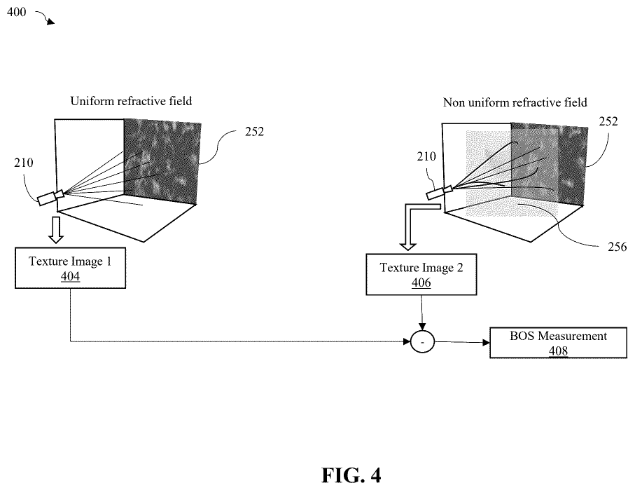

FIG. 4 illustrates the generation of BOS measurement 408 from the schlieren effect for airflow control, reconstruction and imaging, according to some embodiments. FIG. 4 shows an environment 400 of the Background Oriented Schlieren (BOS) measurement 408, demonstrating how light rays are refracted when passing through a non-uniform refractive field and a uniform refractive field, resulting in measurable distortions in a textured background. The setup compares the behavior of light rays propagating through a uniform refractive field versus a non-uniform refractive field, highlighting the impact of density variations within the observed medium, such as airflow.

Referring to FIG. 4, the environment illustrates the case where the light rays pass through a non-uniform refractive field and uniform field. FIG. 4 is described with reference to the description of FIG. 2B. The non-uniform refractive field may be a medium with one or more of airflow variations, temperature gradient variations, or other density variations. In this scenario, the non-uniform refractive index causes the light rays to bend which is captured by the camera 210 as the light rays travel in the medium distorting the observed texture. This distorted version of the texture of non-uniform refractive field is captured as “Texture Image 2” 406 by the camera 210. The non-uniform refractive field leads to measurable shifts in the texture pattern.

The uniform refractive field may be for a medium where there are no temperature variations in the airflow, the refractive field distribution is uniform. Thus, for such a medium the air density does not fluctuate significantly. In this case, the light rays propagating from the patterned wall 252 to the camera 210 travel in a straight line, as there are no variations in the refractive index of the medium (the air) to alter their paths. The uniform refractive field ensures that light rays move predictably and directly from the background propagating from the patterned wall 252 to the camera 210 without any distortion, where the distorted version of the texture image of uniform field is captured as “Texture image 1” 404.

The BOS measurement 408 is calculated as the difference between the observed texture images. Specifically, the BOS measurement quantifies the displacement or distortion between the “Texture Image 1” 404 (corresponding to the uniform refractive field) and the “Texture Image 2” 406 (corresponding to the non-uniform refractive field). This difference is a result of the refractive distortions caused by density variations in the medium, enabling the visualization and quantification of the schlieren effect.

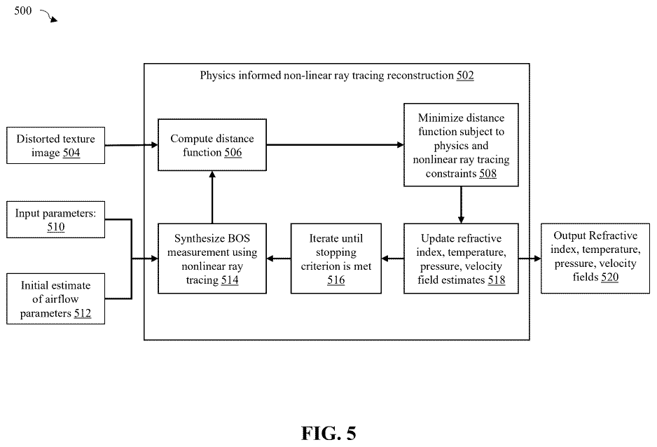

FIG. 5 illustrates a flowchart illustrating the schematics of a physics informed nonlinear ray tracing reconstruction, according to some embodiments. Particularly, FIG. 5 shows a flowchart 500 which includes the description of the Physics informed nonlinear ray tracing reconstruction process 502. The flowchart 500 includes operations for obtaining input parameters 510 and an initial estimate of airflow parameters 512 and capturing a distorted texture image 504. The flowchart 500 further includes operations for computing distance function 506, minimizing the distance function subject to physics and nonlinear ray tracing constraints 508, synthesizing BOS measurement using nonlinear ray tracing 514, iterating until stopping criterion is met 516, updating refractive index, temperature, pressure, velocity field estimates 518, outputting refractive index, temperature, pressure, velocity fields 520.

The flowchart 500 also describes a physics informed nonlinear ray tracing reconstruction of a temperature, pressure, and velocity distribution of an airflow in a computational domain. The physics informed nonlinear ray tracing reconstruction 502 takes as input, a distorted texture image 504 that is captured by a camera after propagating through a nonhomogeneous refractive field of the airflow. Other inputs to the physics informed nonlinear ray tracing reconstruction 502 include input parameters 510 and an initial estimate of airflow parameters 512. The input parameters 510 include a true texture image that is emitted or projected by a light source, geometric information of the size of the volume being monitored and locations of the camera and light source within the volume, and control parameters of a source of the airflow such as input temperature and velocity.

An estimated distorted texture image is generated from the initial estimate of the airflow parameters 512. The estimated distorted texture image is compared at block 506 with the observed distorted texture image from the camera. The distance between the estimated distorted texture image and the observed distorted texture image is parameterized as a distance function at the output of block 506. At block 508, the distance function is minimized subject to constraints related to the physics of the airflow in the medium and nonlinear ray tracing. The minimization of the distance function yields an estimate of airflow parameters including the temperature, pressure and velocity fields. At block 518, the refractive index and the airflow parameters estimated at 508 are updated.

The updated refractive index and the airflow parameters are output at block 520. The updated refractive index and the airflow parameters are then used for the next iteration as the initial estimate of airflow parameters 512 and the process illustrated in flowchart 500 is iterated at 516 until a stopping criterion is met. The stopping criterion may include, for example, an indication that the entire volume within the medium has been analyzed or a predefined time period has lapsed from the commencement of the reconstruction process 502. In some embodiments, the stopping criterion may include an external interrupt provided by another computer program or an operator.

### Ray Tracing Formalism

Various embodiments rely on ray tracing to model the propagation of light through a field of changing refractive index. Accordingly, some embodiments use the image formation model described by refractive radiative transfer equation (RRTE), which is described in the below section.

### Nonlinear Ray Tracing

A light ray parameterized by a position, x, and direction v, will propagate through an inhomogeneous medium according to

$$\frac{d x}{d t} = v , \frac{d v}{d t} = η ∇ η . \qquad ( 1 )$$

In the absence of absorption and emission, basic radiance is conserved along a ray.

Define a light ray r_{s↔w} as the set of points traversed by light between its endpoints (xₛ,vₛ) at the camera sensor, and (x_{w},v_{w}) at the back-wall. We can formulate the bijective ray tracing mapping [symbol] from the camera sensor to the back-wall as

$$( {x}_{w} , {v}_{w} ) = {𝒯}_{s \to w} ( {x}_{s} , {v}_{s} , η ) := \{ \begin{matrix}v = {\int }_{{r}_{s \to w}} η ( x ( τ ) ) ∇ η ( x ( τ ) d τ \\ x = {\int }_{{r}_{s \to w}} v ( τ ) d τ\end{matrix} \qquad ( 2 )$$

where τ denotes an infinitesimal step along the ray path. Note that for a given initial endpoint (xₛ,vₛ) and refractive field map η, the ray path r_{s↔w} and endpoint (x_{w},v_{w}) are fully determined using (2).

Ray tracing may be performed using Monte Carlo estimation by shooting rays from the camera towards random points on the back-wall and evaluating their trajectories using (2). However, directly integrating the ray tracing equations can be an expensive operation. Instead, some embodiments use a quasi-linear approximation that is faster than direct integration with little deviation from the original, true path.

### Quasi-Linear Ray Tracing Approximation

Consider an initial endpoint (x₀,v₀) located at the camera sensor and pointing toward an arbitrary location on the backwall. Since the change in refractive index is small, the trajectory of the light ray may be approximated as a straight line, x(t)≈x̅(t)=x₀+tv₀, for t∈(0, D], where D is the total distance from the camera to the backwall. Then the direction of a ray along the path x̅ is approximated by

$$\tilde{v} ( t ) \approx {\int }_{0}^{t} η ( \overline{x} ( τ ) ) ∇ η ( \overline{x} ( τ ) ) d τ + {v}_{0} . \qquad ( 3 )$$

Finally, given the computed v(t) values, the final position x(t) is approximated by

$$\tilde{x} ( t ) \approx {\int }_{0}^{t} \tilde{v} ( τ ) d τ + {x}_{0} . \qquad ( 4 )$$

Importantly, the linear approximation to the path is only used for querying the refractive index field. The resulting position and direction at the backwall are used in the pixel intensity calculations, i.e.,

$$( {x}_{w} , {v}_{w} ) = {\tilde{𝒯}}_{s \to w} ( {x}_{s} , {v}_{s} , η ) := ( \tilde{x} ( D ) , \tilde{v} ( D ) ) . \qquad ( 5 )$$

### Image Formation Model

For a given pixel j on the sensor, the intensity Iⱼ may be described as

$${I}_{j} = {\int }_{A} {\int }_{Ω} {W}_{j} ( {x}_{s} ) {L}_{wall} ( {x}_{w} , {v}_{w} ) \frac{〈 {\hat{n}}_{w} , {v}_{w} 〉}{‖ {r}_{s ↔ w} ‖} {dv}_{s} {dx}_{s} . \qquad ( 6 )$$

where (x_{w},v_{w}) are obtained using [symbol] , Wⱼ is the camera filter function, L_{wall}(x,v) is the luminance of the back plane, [symbol] \hat{n}_{w},v_{w} [symbol] is the cosine of the angle between the back-wall normal \hat{n}_{w} and the incident ray direction at the back-wall v_{w}, ∥r_{s↔w}∥ is the length of the ray path. The total intensity for the pixel integrates over all incoming directions, Ω, as well as over the area of the sensor pixel, A. Here, the camera filter may be approximated with the triangular function

$${W}_{j} ( x ) = max ( \frac{{p}_{w}}{2} - \vert x - {x}_{j} \vert , 0 ) \cdot max ( \frac{{p}_{h}}{2} - \vert y - {y}_{j} \vert , 0 ) \qquad ( 7 )$$

where p_{w} and pₕ are the pixel width and height, respectively, and (xⱼ,yⱼ) is the pixel center. This filter has the benefit of having non-zero gradient within the pixel's extents.

### Light Source Model

Some embodiments consider two cases, one in which the back wall is a textured light source, and another where the back wall is fully diffused and is illuminated by an emitter, e.g., a light projector. In the case where the back wall is a source, L_{wall} is known and can be queried directly. In practice, this would be the same as looking up a texture.

If the wall is modelled as being illuminated by a pinhole projector with a finite focal length, then a point, x_{w}, on the back plane will be illuminated by a single point from the projector. Supposing that the projector is located at position xₑ, then

$${L}_{wall} ( {x}_{w} , {v}_{w} ) = 𝒫 ( {v}_{e} ( {x}_{w} , {v}_{w}^{*} , {x}_{e} ) ) \frac{〈 {\hat{n}}_{w} , {v}_{w}^{*} 〉}{‖ {r}_{w ↔ e} ‖} , \qquad ( 8 )$$

where vₑ is the ray's direction on the emitter, v_{w}* is the incoming ray direction from the emitter at the backwall, and [symbol] is the image displayed by the projector.

In (8) above, the known quantities are x_{w} and xₑ. Some embodiments use ray tracing to find the incoming ray direction v_{w}* at the wall and the outgoing ray direction vₑ at the emitter as a function of x_{w}, xₑ and η. In order to find the path between the emitter and the wall, the shooting method may be used to solve for the initial direction from the wall that would reach the emitter position:

$${v}_{w}^{*} = arg {min}_{{v}^{*}} {‖ {x}_{e} - {\tilde{T}}_{w \to e} ( {x}_{w} , {v}^{*} , η ) ‖}^{2} . \qquad ( 9 )$$

Once a valid path r_{w→e} is determined, the outgoing direction vₑ may be evaluated at the emitter and consequently the image [symbol] may be sampled. Note that since the tracing procedure, [symbol] , is linear and differentiable, the above equation (9) my be solved using a single linear solve and differentiate with respect to n using implicit differentiation.

Finally, the overall ray tracing procedure that generates the flow image I_{flow}= [symbol] (xₛ,vₛ,xₑ, [symbol] ,η) may be expressed using a combined BOS operator [symbol] , such that,

$$( 10 )$$

$$ℬ ( {x}_{s} , {v}_{s} , {x}_{e} , 𝒫 , η ) := {\int }_{A} {\int }_{Ω} {W}_{j} ( {x}_{s} ) 𝒫 ( {v}_{e} ( {x}_{w} , {v}_{w}^{*} , {x}_{e} ) ) \frac{〈 {\hat{n}}_{w} , {v}_{w}^{*} 〉 〈 {\hat{n}}_{w} , {v}_{w} 〉}{‖ {r}_{w ↔ e} ‖ ‖ {r}_{s ↔ w} ‖} {dv}_{s} {dx}_{s} ,$$

where (x_{w},v_{w})= [symbol] (xₛ,vₛ,η), and v_{w}* is given by the equation (9).

In summary, the tracing procedure proceeds as follows. Sample a ray on the camera plane and trace it to the back wall through the volume. Then from the wall point, solve the minimization problem as described by the equation (9). Once the connection to the projector is made, equation (10) may be used to calculate the intensity on the sensor pixel.

### Physics-Informed BOS Tomography

Reconstructing the airflow φ can be formulated as a tomographic inverse problem given BOS measurements and boundary conditions specifying the flow parameters of the room at a boundary region Γ. Since the single-camera BOS tomography problem is highly ill-posed, some embodiments propose to regularize the inversion using a physics-informed loss that imposes a Boussinesq approximation to the incompressible Navier-Stokes equation coupled with the heat-transfer equation.

### Inverse Problem

Let the true airflow φ be parameterized by the fields (T*,p*,u*) and recalling that the refractive index field η* is related to T* according to

$$η = 1 + {ρ}_{0} G \frac{{T}_{0}}{T} .$$

Some embodiments propose to reconstruct φ by solving the following constrained optimization problem:

$$\begin{matrix}{min}_{T , p , u} & {λ}_{1} {ℒ}_{BOS} ( η ) + {λ}_{2} {ℒ}_{Γ} ( T , p , u ) + {λ}_{3} {ℒ}_{PDE} ( T , p , u )\end{matrix} \qquad ( 11 )$$

$$subject to \qquad η = 1 + {ρ}_{0} G \frac{{T}_{0}}{T} ,$$

where the schlieren loss is defined as

$${ℒ}_{BOS} ( η ) := {\sum }_{j} {‖ {I}_{flow} ( j ) - {\sum }_{{x}_{s} ∈ {𝒩}_{j}} ℬ ( {x}_{s} , {v}_{s} , {x}_{e} , 𝒫 , η ) ‖}_{2}^{2} , \qquad ( 12 )$$

where j denotes the pixel index, and [symbol] is spatial region belonging to the pixel j. Differentiating the schlieren loss with respect to the refractive field η can be performed efficiently using automatic differentiation with adjoint-gradient for the [symbol] operator and exploiting the implicit function theorem in evaluating the gradient of v_{w}* with respect to η through equation (9).

The boundary loss is a Euclidean distance between the computed fields and the true fields at collocation points on the boundary

$${{{ℒ}_{Γ} ( T , p , u ) = ‖ ( {T}_{n}^{*} , {p}_{n}^{*} , {u}_{n}^{*} ) {\vert}_{Γ} - ( {T}_{n} , {p}_{n} , {u}_{n} ) \vert}_{Γ} ‖}_{2}^{2} , \qquad ( 13 )$$

where subscript n denotes the field divided by its maximum value.

### Physics-Informed Loss

The airflow is assumed to be a steady, incompressible, Newtonian fluid that is governed by the Boussinesq approximation for buoyancy-driven flows. The underlying physics of the airflow is then imposed by combining loss functions obtained from the nondimensional steady-state Navier-Stokes equations in the Boussinesq approximation. These are defined in terms of the mass conservation, momentum conservation, and heat transfer equation residuals as

$${r}_{mass} ( x ) = ∇ \cdot u , \qquad ( 14 )$$

$${r}_{mom} ( x ) = ( u \cdot ∇ ) u + ∇ p - \frac{1}{Re} {∇}^{2} u + Ri {T}_{nd} {e}_{g} ,$$

$${r}_{heat} ( x ) = ( u \cdot ∇ ) {T}_{nd} - \frac{1}{Pe} {∇}^{2} {T}_{nd} .$$

Here, ∇ and ∇² are the spatial gradient and Laplacian operators in 3D, respectively, x is the nondimensional coordinate scaled by a characteristic length scale L, u=(u,v,w) is the nondimensional velocity scaled by a characteristic velocity scale U, and p is the nondimensional pressure deviation from hydrostatic equilibrium scaled by p₀=ρ₀U², where ρ₀ is a reference density. The nondimensional temperature fluctuation T_{nd} is obtained from the dimensional temperature T as

$${T}_{nd} = \frac{T - {T}_{0}}{{T}_{in} - {T}_{0}} ,$$

where Tᵢₙ is the inlet temperature and T₀ is a reference temperature. Additional parameters include the acceleration due to gravity g and its unit vector e_{g}, kinematic viscosity v, coefficient of thermal diffusivity α, and coefficient of thermal expansion β, leading to the nondimensional Reynolds, Péclet, and Richardson numbers, defined as follows:

$$Re = \frac{UL}{v} , Pe = \frac{UL}{a} , Ri = \frac{g β ( {T}_{in} - {T}_{0} ) L}{{U}^{2}} . \qquad ( 15 )$$

Following the PINNs framework, the residual equations (14) are combined to form the physics-informed loss

$${ℒ}_{PDE} = {\sum }_{i = 1}^{{N}_{c}} {γ}_{1} {r}_{mass}^{2} ( {x}_{i} ) + {γ}_{2} {‖ {r}_{mom} ( {x}_{i} ) ‖}_{2}^{2} + {γ}_{3} {r}_{heat}^{2} ( {x}_{i} ) , \qquad ( 16 )$$

where γ_{1,2,3} are scalar multipliers that balance the weight of each residual, and x_{i=1, . . . , N}_{_{C}} are coordinates of the collocation points uniformly sampled in the computational domain at each iteration.

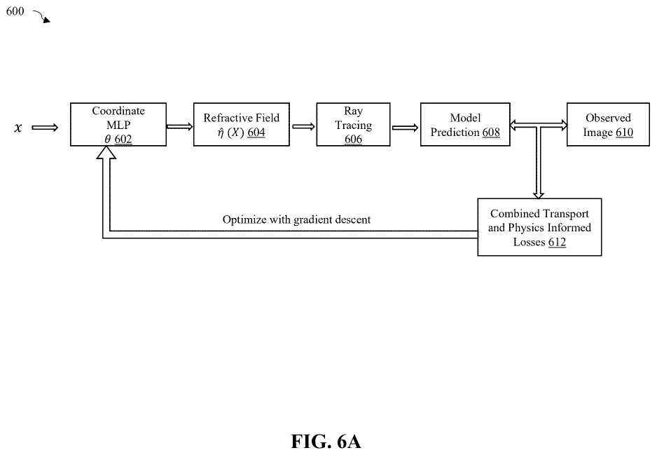

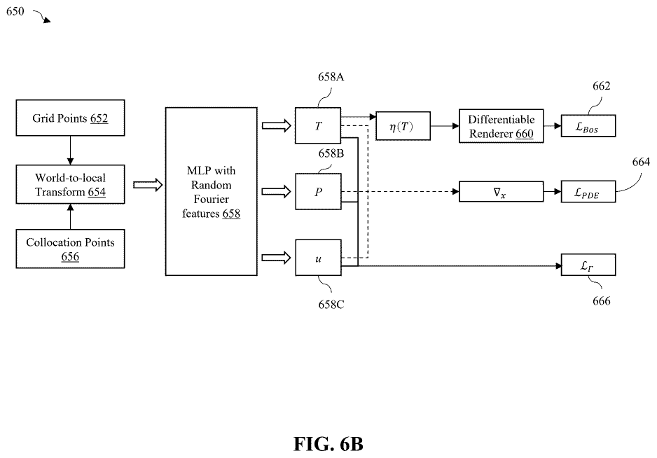

FIG. 6A illustrates a flowchart 600 for updating airflow parameters by updating weights of a multilayer perceptron (MLP) of the PINN 112 of FIG. 1B, according to some embodiments. FIG. 6B depicts a computational framework of a multilayer perceptron (MLP) for evaluating a combination of distances of a BOS, according to some embodiments. FIG. 6A is described with reference to some components of FIG. 6B which is described in detail subsequently. The update of the airflow parameters is performed by updating weights of a multilayer perceptron (MLP) 602 such that the output of the MLP are the temperature 658A, pressure 658B, velocity 658C, and refractive field 604 values of the airflow at specific geometric coordinates 652, 656 of the computational volume and whereby the update is performed such that rays of light propagating from the light source to the camera produce an estimated distorted texture image 608 that minimizes a distance to the observed distorted texture image 610 as well as ensures that the distribution of airflow parameters in the computational volume obey known physical equations that describe the flow of air in a volume. The minimization of the distance to the observed distorted texture image 610 and the obeying of the distribution of airflow parameters in the computational volume to the known physics equations that describe the flow of air in the volume is conducted by minimizing a combined transport and physics informed losses 612, wherein the minimization is optimized with gradient descent.

### BOS Imaging Formulation

### Airflow Imaging Setup

Some embodiments consider a BOS imaging scenario comprising an air-filled room, a camera, and either a patterned background wall or a light source that can project a pattern on the backwall, as shown in FIG. 3A. An inlet on the side wall injects an airflow into the room with a temperature that differs from the ambient temperature. When no air is flowing, the camera captures a reference image I_{ref} of the backwall pattern. When the inlet blows the airflow into the room, the change in density of the air induces a gradient in its refractive index n, causing light rays passing through the air to bend. A classical BOS measurement computes a displacement in the pixels between the reference image I_{ref} and the image I_{flow} obtained for the backwall in the presence of the airflow. In contrast, various embodiments adopt a ray tracing framework where luminance from the backwall is traced through an estimate of the refractive field and compared to the flow image I_{flow}.

Let φ denote the 3D airflow volume that is parameterized by the temperature, pressure, and velocity fields, i.e., φ:=(T,p,u), where T and p are scalar fields, and u is a vector field in [symbol] . For a gas, the refractive index depends linearly on the density p of the gas via the Gladstone-Dale equation η=1+Gρ, where G is the Gladstone-Dale coefficient. Assuming the pressure variation of air in a room is small, then by the ideal gas law, the refractive index is related to temperature using

$$η ( T ) = 1 + {ρ}_{0} G \frac{{T}_{0}}{T} , \qquad ( 17 )$$

where ρ₀ is the ambient density and T₀ is the ambient temperature. It can be seen from equation (17) that changes in the air temperature cause changes in the density and thus the refractive index.

### Neural Representation of the Airflow Fields

Some embodiments are based on the realization that single-view 3D BOS has inherent ambiguities along the view direction. Accordingly, various embodiments propose to use a PINN framework so the physics of airflow can regularize the reconstruction. FIG. 6B depicts a computational framework of a multilayer perceptron (MLP) for evaluating a combination of distances of a BOS, according to some embodiments. The distances comprise i.) a BOS loss 662 that uses nonlinear ray tracing to generate an estimated distorted texture image and compares it to the observed distorted texture image, ii.) a partial differential equation (PDE) loss 664 that ensures that the set of airflow parameters that are output by the MLP obey known physical equations that describe the flow of air in a volume, and iii.) a boundary loss 666 that ensures the value of the airflow parameters are similar to the parameters controlled by the airflow source.

The PINN consists of a multilayer perceptron (MLP) 658 whose outputs are the T, p, and u fields 658A, 658B, and 658C respectively. Two types of inputs are provided to the MLP 658, one type are coordinates of grid points 652 that are sampled on a regular voxelized grid that span the space of the airflow volume. Another type of input are coordinates of collocation points 656 that are sampled randomly from the space of the airflow volume. The coordinates of grid points 652 are first transformed from the physical space of airflow volume to a space that is suitable for the MLP 658 to process as input using a world-to-local transform 654. The world-to-local transform 654 shifts and scales the world coordinates to a range of values that are acceptable for an MLP input. The transformed input coordinates are then transformed via random Fourier feature embeddings, followed by three fully connected layers of width 64 and SIREN activations. The last layer is a tanh activation that maps the outputs to their respective ranges. Referring to FIG. 6B, the computational framework 650 of the MLP architecture shows how the outputs are used in the computation of different optimization losses. Since ray tracing through the MLP is slow, an intermediate step that first samples the MLP on a voxel grid (grid points 652) is used. The output of this step is the T field 658A which is then used to estimate the refractive index η(T) to perform ray tracing in the differentiable renderer 660 and compute the schlieren loss [symbol] 662. The differentiable renderer 660 performs ray-tracing of light rays from the background image 252 to the camera 210 according to the refractive radiative transfer equation (RRTE) using the nonlinear or quasilinear approximation as discussed in the embodiments of this invention. On the other hand, the MLP is directly sampled at collocation points 656 throughout the computational domain to compute the physics-informed loss [symbol] 664, and the MLP is sampled in the boundary region Γ to determine [symbol] 666.

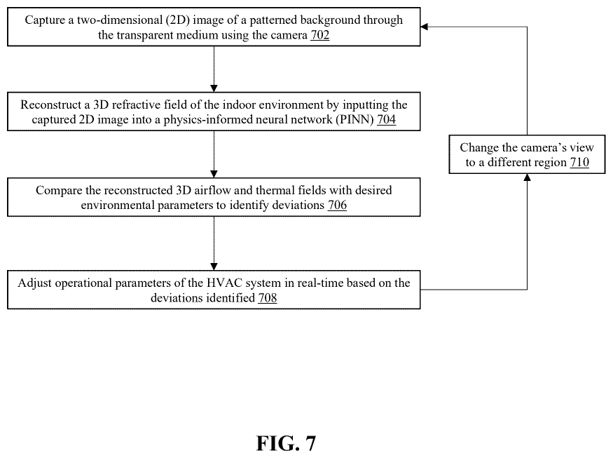

FIG. 7 depicts a flowchart 700 illustrating the airflow control, reconstruction and imaging, according to some embodiments. The flowchart 700 represents a comprehensive process flow for monitoring, analyzing, and regulating indoor environmental conditions using advanced imaging and computational techniques. The process comprises capturing 702 a two-dimensional (2D) image of a patterned background through a transparent medium using a camera. The patterned background serves as a reference for detecting distortions caused by changes in the refractive index of the medium due to airflow or thermal variations. The captured 2D image is fed into a physics-informed neural network (PINN), which reconstructs 704 a three-dimensional (3D) refractive field of the indoor environment. The PINN leverages prior physical models of airflow and thermal dynamics, alongside the captured data, to accurately estimate the spatial variations in airflow and temperature.

The 3D refractive field is compared 706 against desired environmental parameters, such as optimal temperature ranges, airflow patterns, or thermal comfort metrics, to identify deviations or anomalies. The deviations may include uneven airflow, overheating zones, or insufficient cooling in certain areas. Based on the identified deviations, the system 50 adjusts 708 the operational parameters of the HVAC system in real time. Adjustments may include altering air supply rates, changing vent positions, or modulating cooling and heating outputs to restore desired conditions. This real-time feedback loop ensures the indoor environment remains comfortable. The field of view of the camera may then be changed 710 to a different region in the indoor environment and the operations 702-708 may be repeated in the next iteration until the process is terminated.

Thus, the system 50 may continuously monitor the indoor environment by capturing updated 2D images and feeding them back into the process. This ongoing monitoring ensures any new changes in the indoor environment, such as increased occupancy or external temperature fluctuations, are quickly addressed. Additionally, operational parameters of the HVAC system are adjusted dynamically to maintain thermal comfort while optimizing energy efficiency. For instance, in a residential setting, the system 50 may reduce cooling in unoccupied rooms while increasing airflow in living areas. In commercial spaces like office buildings, the system 50 may ensure consistent airflow in crowded conference rooms while saving energy in vacant spaces.

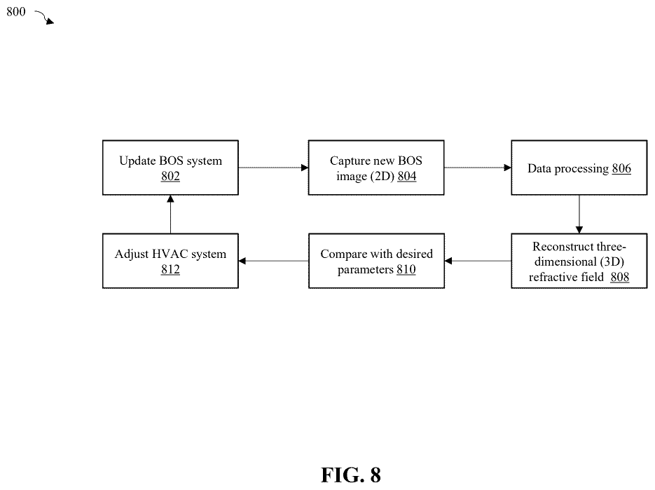

FIG. 8 depicts a flow diagram of control feedback for HVAC system for airflow control, reconstruction and imaging, according to some embodiments. FIG. 8 shows an environment 800 that illustrates the feedback mechanism operates continuously, ensuring real-time monitoring and optimization of indoor environmental conditions. The loop incorporates the Background Oriented Schlieren (BOS) system 802, which is periodically updated to maintain calibration and system accuracy. The update process involves recalibrating the camera, ensuring proper alignment of the patterned background, and adjusting the imaging setup to account for any changes in environmental conditions or system parameters. The updated BOS system 802 serves as the foundation for capturing precise and reliable data.

Following this, a new BOS image (2D) is captured 804. The image captures the refractive distortions caused by airflow or thermal variations in the indoor environment. The distortions aid in identifying the density gradients of the transparent medium. The newly captured BOS image is subjected to data processing 806, where advanced computational techniques are applied to extract meaningful information. This processed data is input into a physics-informed neural network (PINN), which reconstructs 808 the three-dimensional (3D) refractive field. The 3D reconstruction provides a detailed representation of the airflow and thermal gradients throughout the monitored space, offering insights into the dynamics of the indoor environment.

The reconstructed 3D refractive field is compared 810 with desired environmental parameters, such as predefined temperature distributions, airflow patterns, or comfort indices. This comparison identifies deviations from the target conditions, such as thermal discomfort zones, areas of excessive airflow. In response to the detected deviations, the system 50 adjusts 812 the HVAC system parameters in real time. The adjustments may involve fine-tuning the air supply rates, redistributing airflow, or altering heating and cooling settings to address the identified anomalies. The loop runs as a feedback loop into the BOS system update 802, incorporating the latest adjustments and environmental data to refine subsequent iterations.

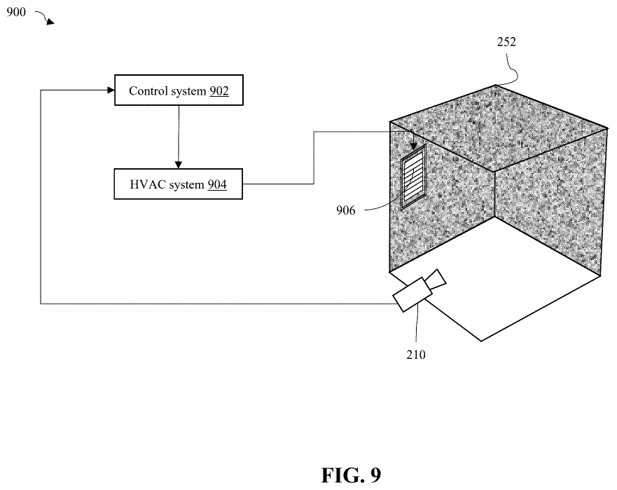

FIG. 9 depicts a flow diagram illustrating a use case for airflow control, reconstruction and imaging, according to some embodiments. The illustrated system 900 represents a comprehensive use case of an airflow monitoring and control setup designed for indoor environments, integrating a patterned background 252, a camera 210, an HVAC system 904, and a control system 902. At the core of this system 900 lies the control system 902, which serves as the central computational hub that orchestrates the interactions between the camera 210 and the HVAC system 904. The control system 902 collects visual data captured by the camera 210, processes the data captured using advanced imaging techniques such as Background Oriented Schlieren, and provides actionable insights to regulate airflow. The camera 210 is strategically positioned to observe the patterned background 252, which serves as a reference for airflow visualization. When air flows through the vent 906 connected to the HVAC system 904, the airflow interacts with the patterned background, causing distortions in the texture visible to the camera 210. These distortions occur due to the Schlieren effect, which leverages changes in the refractive index of air caused by variations in temperature, humidity, or velocity within the airflow.

The system 900 identifies such distortions, computes the BOS measurements, and enables the control system 902 to assess the airflow's behavior, including speed, direction, and turbulence. The data empowers the HVAC system 904 to dynamically adjust its operations, such as altering air supply, vent positions, or airflow distribution, to optimize indoor conditions. For example, if uneven airflow or stagnation is detected in a corner of the room, the system 900 may redirect air supply to that specific area, ensuring uniform comfort. In smart homes, the setup may enhance energy efficiency by reducing airflow to unoccupied rooms and directing the system 900 where needed, while in office buildings, the system 900 ensures consistent comfort for all occupants. Specialized environments such as hospitals and data centers greatly benefit from such precision; for instance, in a hospital operating room, the system 900 may maintain sterile airflow to prevent contamination, while in data centers, the system 900 can detect and mitigate hotspots caused by inadequate cooling near servers. Additionally, the system 900 may predict airflow behavior using AI-based algorithms trained on historical data, enabling proactive adjustments to HVAC operations, such as increasing airflow in anticipation of high foot traffic in malls or large commercial spaces. The system's 900 scalability allows deployment across multiple rooms or zones in extensive facilities like airports or hotels. Furthermore, integrating IoT sensors, such as occupancy detectors, can enhance responsiveness by automatically adjusting airflow based on real-time room occupancy.

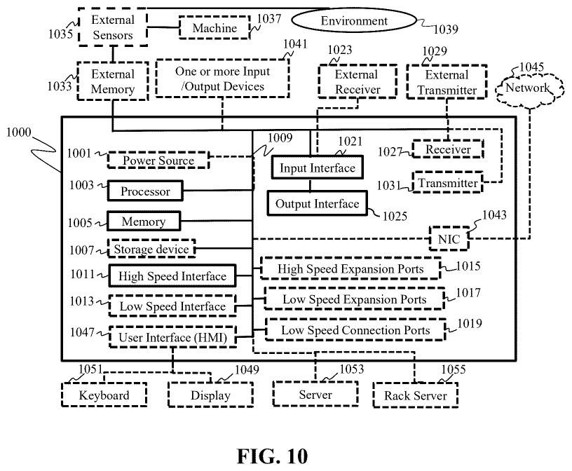

FIG. 10 shows a schematic diagram of some components of a system 1000 for airflow control, reconstruction and imaging, in accordance with some embodiments of the present disclosure. The system 1000 includes a power source 1001, a processor 1003, a memory 1005, a storage device 1007, all connected to a bus 1009. Further, a high-speed interface 1011, a low-speed interface 1013, high-speed expansion ports 1015 and low speed connection ports 1017, can be connected to the bus 1009. In addition, a low-speed expansion port 1019 is in connection with the bus 1009. Further, an input interface 1021 can be connected via the bus 1009 to an external receiver 1023 and an output interface 1025. A receiver 1027 can be connected to an external transmitter 1029 and a transmitter 1031 via the bus 1009. Also connected to the bus 1009 can be an external memory 1033, external sensors 1035, machine(s) 1037, and an environment 1039. Further, one or more external input/output devices 1041 can be connected to the bus 1009. A network interface controller (NIC) 1043 can be adapted to connect through the bus 1009 to a network 1045, wherein data or other data, among other things, can be rendered on a third-party display device, third party imaging device, and/or third-party printing device outside of the system 1000.

The memory 1005 may store instructions that are executable by the system 1000 and any data that can be utilized by the methods and systems of the present disclosure. The memory 1005 can include random access memory (RAM), read only memory (ROM), flash memory, or any other suitable memory systems. The memory 1005 can be a volatile memory unit or units, and/or a non-volatile memory unit or units. The memory 1005 may also be another form of computer-readable medium, such as a magnetic or optical disk.

The storage device 1007 can be adapted to store supplementary data and/or software modules used by the system 1000. The storage device 1007 can include a hard drive, an optical drive, a thumb-drive, an array of drives, or any combinations thereof. Further, the storage device 1007 can contain a computer-readable medium, such as a floppy disk device, a hard disk device, an optical disk device, or a tape device, a flash memory or other similar solid-state memory device, or an array of devices, including devices in a storage area network or other configurations. Instructions can be stored in an information carrier. The instructions, when executed by one or more processing devices (for example, the processor 1003), perform one or more methods, such as those described above.

The system 1000 can be linked through the bus 1009, optionally, to a display interface or user Interface (HMI) 1047 adapted to connect the system 1000 to a display device 1049 and a keyboard 1051, wherein the display device 1049 can include a computer monitor, camera, television, projector, or mobile device, among others. In some implementations, the system 1000 may include a printer interface to connect to a printing device, wherein the printing device can include a liquid inkjet printer, solid ink printer, large-scale commercial printer, thermal printer, UV printer, or dye-sublimation printer, among others.

The high-speed interface 1011 manages bandwidth-intensive operations for the system 1000, while the low-speed interface 1013 manages lower bandwidth-intensive operations. Such an allocation of functions is an example only. In some implementations, the high-speed interface 1011 can be coupled to the memory 1005, the user interface (HMI) 1045, and to the keyboard 1051 and the display 1049 (e.g., through a graphics processor or accelerator), and to the high-speed expansion ports 1015, which may accept various expansion cards via the bus 1009. In an implementation, the low-speed interface 1013 is coupled to the storage device 1007 and the low-speed expansion ports 1017, via the bus 1009. The low-speed expansion ports 1017, which may include various communication ports (e.g., USB, Bluetooth, Ethernet, wireless Ethernet) may be coupled to the one or more input/output devices 1041. The system 1000 may be connected to a server 1053 and a rack server 1055. The system 1000 may be implemented in several different forms. For example, the system 1000 may be implemented as part of the rack server 1055.

The above description provides exemplary embodiments only, and is not intended to limit the scope, applicability, or configuration of the disclosure. Rather, the above description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the above description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicated like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a FIG. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the program modules may be combined or distributed as desired in various embodiments.

Embodiments of the present disclosure may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments. Although the present disclosure has been described with reference to certain preferred embodiments, it is to be understood that various other adaptations and modifications can be made within the spirit and scope of the present disclosure. Therefore, it is the aspect of the append claims to cover all such variations and modifications as come within the true spirit and scope of the present disclosure.

What is claimed is:

1. A background-oriented Schlieren (BOS) method suitable for reconstructing a three-dimensional (3D) refractive field of a transparent medium using a single camera, the method comprising:
capturing a two-dimensional (2D) image of a patterned background through the transparent medium using the camera;
training a physics-informed neural network (PINN) to produce a change of a refractive index of the transparent medium that reduces a difference between the captured 2D image and a 2D image reconstructed from the 3D refractive field using a nonlinear ray tracing, wherein the PINN incorporates governing equations of fluid dynamics into a loss function of the training to regularize solution space of the 3D refractive field by penalizing inconsistencies with the governing equations; and
generating a reconstructed 3D refractive field that corresponds to the change in the refractive index of the medium.

2. The BOS method of claim 1, further comprising operating a thermal control system based on the reconstructed 3D refractive field.

3. The BOS method of claim 1, wherein the governing equations of fluid dynamics include at least one of the Navier-Stokes equations, mass conservation equations, or heat transfer equations.

4. The BOS method of claim 1, further comprising:
controlling a light projector to illuminate a backwall with a textured pattern forming the patterned background, wherein the projector is spatially distance from the camera such that a spatial offset between the camera and the projector introduces angular information into a single-view setup.

5. The BOS method of claim 1, wherein the PINN is configured to incorporate the Boussinesq approximation, including steady-state incompressible Navier-Stokes and heat transfer equations, to regularize the reconstruction of the 3D refractive field.

6. The BOS method of claim 1, wherein the nonlinear ray tracing includes a quasi-linear ray tracing approximation which estimates light ray trajectories by assuming small changes in refractive index to reduce computational cost while maintaining accuracy in modeling light propagation.

7. The BOS method of claim 3, wherein the governing equations of fluid dynamics include residuals from mass conservation, momentum conservation, and heat transfer equations, and the PINN minimizes these residuals to ensure a physically consistent reconstruction of airflow.

8. The BOS method of claim 1, further comprising:
optimizing the PINN by evaluating gradients of the loss function derived from BOS measurements and governing physical laws, based on automatic differentiation and an implicit function theorem.

9. The BOS method of claim 1, wherein the PINN is trained using a loss function that combines contributions from a BOS operator, boundary conditions, and partial differential equation residuals, with each loss term weighted to balance reconstruction accuracy and physical consistency.

10. The BOS method of claim 4, wherein the backwall pattern is illuminated by a pinhole projector, and the nonlinear ray tracing is performed using a refractive radiative transfer equation (RRTE) to model light propagation through the refractive index field.

11. The BOS method of claim 1, wherein the reconstruction of the 3D refractive field is parameterized by temperature, pressure, and velocity fields, and the PINN maps the temperature, pressure, and velocity fields to a refractive index field using the Gladstone-Dale equation.

12. The BOS method of claim 1, further comprising controlling a heating, ventilation, and air conditioning (HVAC) system to optimize airflow distribution within an indoor environment, based on the reconstructed 3D refractive field to improve thermal comfort within the indoor environment and energy efficiency of the HVAC system.

13. The BOS method of claim 1, further comprising;
detecting one or more hotspots in a data center by visualizing temperature gradients in airflow patterns based on the reconstructed 3D refractive field; and
generating control commands to control a cooling system, based on the detected one or more hotspots.

14. The BOS method of claim 1, further comprising integrating the reconstructed 3D refractive field into a control system for real-time adjustments to ventilation rates.

15. A method for controlling a heating, ventilation, and air conditioning (HVAC) system based on reconstructed three-dimensional (3D) airflow and thermal fields, the method comprising:
capturing a two-dimensional (2D) image of a patterned background through an indoor environment using a single camera, wherein the captured image is distorted due to variations in a refractive index of air caused by temperature and density gradients;
reconstructing a 3D refractive field of the indoor environment by inputting the captured 2D image into a physics-informed neural network (PINN), wherein the PINN incorporates governing equations of fluid dynamics and heat transfer into its loss function to regularize solution space and infer airflow, temperature, and pressure distributions;
comparing the reconstructed 3D airflow and thermal fields with desired environmental parameters to identify deviations, including uneven temperature zones, air leakage, or inefficient airflow patterns;
adjusting operational parameters of the HVAC system in real-time based on the deviations identified, wherein the adjustments include at least one of: (1) modifying airflow rates by controlling fan speeds, (2) redirecting airflow by adjusting vent orientations, or (3) changing temperature setpoints of heating or cooling units; and
continuously monitoring the indoor environment by updating the captured 2D image and adjusting operational parameters of the HVAC system to maintain thermal comfort and optimize energy efficiency.
